(19) United States
(12) Patent Application Publication
(10) Pub. No.: US 2026/0173949 A1
(43) Pub. Date: Jun. 18, 2026

(54) METHOD OF MANUFACTURING SEMICONDUCTOR PACKAGE

(71) Applicant: Samsung Electronics Co., Ltd., Suwon-si (KR)

(72) Inventor: Kangmo LEE, Suwon-si (KR)

(73) Assignee: Samsung Electronics Co., Ltd., Suwon-si (KR)

(21) Appl. No.: 19/408,575

(22) Filed: Dec. 4, 2025

(30) Foreign Application Priority Data
Dec. 16, 2024 (KR) 10-2024-0187529

(51) Int. Cl. H10W 74/01

(52) U.S. Cl. CPC H10W 74/017; H10W 74/014

(57) ABSTRACT

A method of manufacturing a semiconductor package includes providing a molding apparatus, the molding apparatus including a first mold having a cavity for accommodating a molding material and a second mold for fixedly holding a package substrate having at least one semiconductor chip mounted thereon, attaching a protective tape onto the cavity of the first mold to cover the cavity, the protective tape including a release film and a transparent layer that are sequentially stacked, forming a molding member between the protective tape and the package substrate to cover the at least one semiconductor chip, the molding member bonded to the transparent layer, separating the transparent layer bonded to the molding member and the package substrate from the release film of the protective tape, and irradiating light onto the molding member through the transparent layer to form a marking portion on a bonding surface of the molding member.

### CROSS-REFERENCE TO RELATED APPLICATIONS

This application claims priority under 35 U.S.C. § 119 to Korean Patent Application No. 10-2024-0187529, filed on Dec. 16, 2024 in the Korean Intellectual Property Office (KIPO), the contents of which are herein incorporated by reference in their entirety.

### BACKGROUND

### 1. Field

Example embodiments relate to methods of manufacturing a semiconductor package. More particularly, example embodiments relate to methods of manufacturing a semiconductor package including a marking pattern on a molding member.

### 2. Description of the Related Art

In order to form a marking pattern on a semiconductor package, a laser may be irradiated on a molding member to partially carbonize the molding member. As a size of the semiconductor package decreases, a depth desired for carbonization (e.g., the marking depth) may need to be reduced to secure visibility of the mark pattern. However, the method of irradiating the exposed molding member with the laser may cause problems in that dust is generated due to carbonization and that the marking depth desired to secure a minimum visibility (or a threshold visibility) relatively increases. In addition, a method of adding a temperature-sensitive material to the molding member to increase visibility may not be used for some products and some processes, and may have a problem that the cost increases.

### SUMMARY

Example embodiments provide methods of manufacturing the semiconductor package capable of increasing the visibility of a mark and/or reducing the marking depth.

According to an example embodiment, a method of manufacturing a semiconductor package includes providing a molding apparatus, the molding apparatus including a first mold having a cavity configured to accommodate a molding material and a second mold configured to fixedly hold a package substrate having at least one semiconductor chip mounted thereon, attaching a protective tape onto the cavity of the first mold to cover the cavity of the first mold, the protective tape including a release film and a transparent layer that are sequentially stacked on each other, forming a molding member between the protective tape and the package substrate to cover the at least one semiconductor chip, the molding member being bonded to the transparent layer, separating the transparent layer bonded to the molding member and the package substrate from the release film of the protective tape, and irradiating light onto the molding member through the transparent layer to form a marking portion on a bonding surface of the molding member.

According to an example embodiment, a method of manufacturing a semiconductor package includes providing a molding apparatus, the molding apparatus including a first mold having a cavity configured to accommodate a molding material and a second mold configured to fixedly hold a package substrate having at least one semiconductor chip mounted thereon, attaching a protective tape onto the cavity of the first mold to cover the cavity of the first mold, the protective tape including a release film and a first patterned marking layer of a metal material, forming a molding member between the protective tape and the package substrate to cover the at least one semiconductor chip, the molding member being bonded to the first patterned marking layer, separating the first patterned marking layer bonded to the molding member and the package substrate from the release film of the protective tape, and irradiating light onto the first patterned marking layer to form a marking portion on the first patterned marking layer.

According to an example embodiment, a method of manufacturing a semiconductor package includes providing a molding apparatus, the molding apparatus including a first mold having a cavity configured to accommodate a molding material and a second mold configured to fixedly hold a package substrate having at least one semiconductor chip mounted thereon, attaching a protective tape onto the cavity of the first mold to cover the cavity of the first mold, the protective tape including a release film and a second patterned marking layer including a temperature-sensitive material, filling the molding material between the protective tape and the package substrate so as to cover the at least one semiconductor chip, heating the molding material to form a molding member bonded to the second patterned marking layer and the package substrate, separating the second patterned marking layer bonded to the molding member and the package substrate from the release film of the protective tape, and irradiating light onto the second patterned marking layer bonded to the molding member to form a marking portion on the second patterned marking layer.

Accordingly, because the carbonized molding materials are fixedly held between the transparent layer and the molding member, the visibility of the marking portion may be increased. Therefore, the marking depth desired to secure visibility may be relatively reduced. In addition, visibility may be secured by utilizing a laser having a relatively small power.

In addition, because dust is not generated due to the carbonization of the molding material, marking defects caused by dust may be reduced or eliminated, and thus a separate cleaning process to remove dust may not be needed, thereby improving the efficiency of the process.

### BRIEF DESCRIPTION OF THE DRAWINGS

Example embodiments will be more clearly understood from the following detailed description taken in conjunction with the accompanying drawings. FIGS. 1 to 40 represent non-limiting, example embodiments as described herein.

FIG. 1 is a cross-sectional view illustrating a semiconductor package in accordance with an example embodiment.

FIG. 2 is an enlarged cross-sectional view illustrating the ‘M1’ portion of FIG. 1.

FIG. 3 is a plan view illustrating a semiconductor package in FIG. 1.

FIGS. 4 to 20 are views illustrating a method of manufacturing a semiconductor package in accordance with an example embodiment.

FIGS. 21 to 25 are views illustrating a method of manufacturing a semiconductor package in accordance with an example embodiment.

FIG. 26 is a cross-sectional view illustrating a semiconductor package in accordance with an example embodiment.

FIG. 27 is an enlarged cross-sectional view illustrating the ‘M7’ portion of FIG. 26.

FIGS. 28 to 32 are views illustrating a method of manufacturing a semiconductor package in accordance with an example embodiment.

FIG. 33 is a cross-sectional view illustrating a semiconductor package in accordance with an example embodiment.

FIG. 34 is an enlarged cross-sectional view illustrating the ‘M10’ portion of FIG. 33.

FIGS. 35 to 40 are views illustrating a method of manufacturing a semiconductor package in accordance with an example embodiment.

### DETAILED DESCRIPTION

Hereinafter, some example embodiments will be explained in detail with reference to the accompanying drawings.

As used herein, expressions such as “one of,” “one or more of,” “any one of,” “at least one of,” and “at least one selected from” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

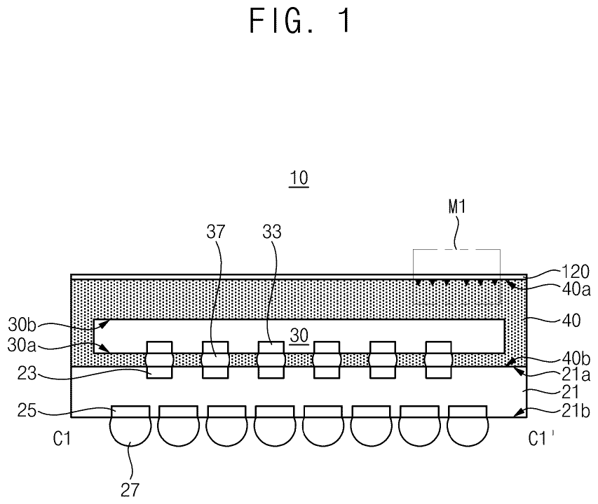

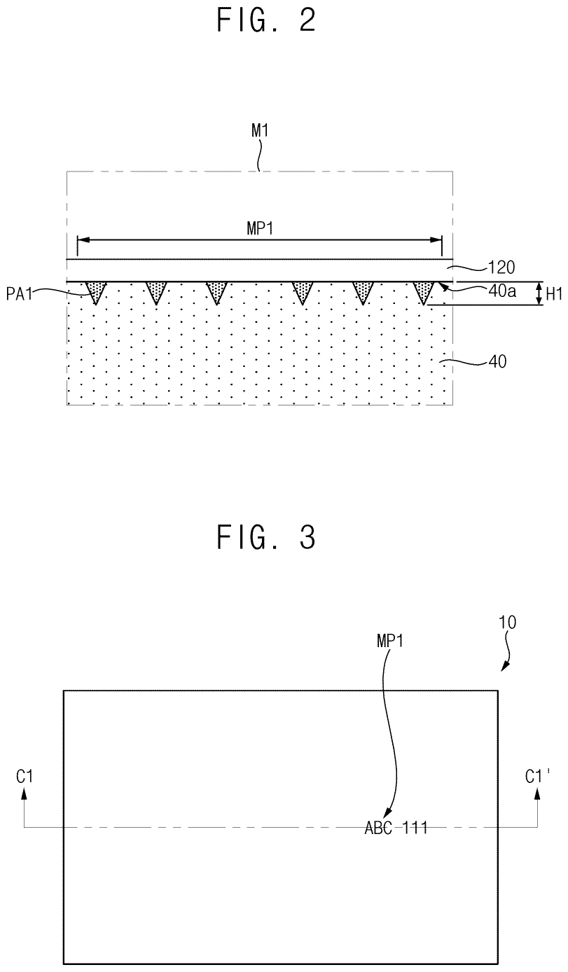

FIG. 1 is a cross-sectional view illustrating a semiconductor package in accordance with an example embodiment. FIG. 2 is an enlarged cross-sectional view illustrating portion ‘M1’ in FIG. 1. FIG. 3 is a plan view illustrating the semiconductor package in FIG. 1. FIG. 1 is a cross-sectional view taken along the line C1-C1′ in FIG. 3.

Referring to FIGS. 1 to 3, a semiconductor package 10 may include a package substrate 21, a semiconductor chip 30 stacked on the package substrate 21, a molding member 40 provided on the package substrate 21 to cover the semiconductor chip 30, and a transparent layer 120 covering an upper surface (e.g., a first surface) 40a of the molding member 40.

In some example embodiments, a package substrate 21 may have a first surface 21a and a second surface 21b opposite to the first surface 21a. The package substrate 21 may include a plurality of first substrate pads 23 disposed on the first surface 21a and a plurality of second substrate pads 25 disposed on the second surface 21b. The package substrate 21 may further include a plurality of external connection members 27 respectively provided on the plurality of second substrate pads 25. For example, the plurality of first and second substrate pads and the plurality of external connection members may include a conductive metal material for electrical connection.

Although only a few substrate pads are illustrated in the figures, it may be understood that this is illustrated as an example and the present inventive concepts are not limited thereto. Accordingly, the number, size, arrangement, and shape of the substrate pads may vary. In addition, although the internal structure of the package substrate is not shown in the figures, the package substrate may include a plurality of insulating layers and a plurality of internal wirings provided within the insulating layers. The plurality of internal wirings may be electrically connected to the substrate pads, respectively.

For example, the plurality of external connection members may be connection members for connecting the semiconductor package 10 to an external device such as a printed circuit board (PCB).

In some example embodiments, the semiconductor chip 30 may have a first surface 30a and a second surface 30b opposite to the first surface 30a. For example, the first surface 30a may be an active surface on which circuits are formed, and the second surface may be an inactive surface. The semiconductor chip 30 may include a plurality of chip pads 33 disposed on the first surface 30a and a plurality of conductive connection members 37 provided on the chip pads 33. For example, the plurality of chip pads and the plurality of conductive connection members 37 may include a conductive metal material for electrical connection.

For example, the semiconductor chip 30 may be mounted on the package substrate 21 via the plurality of conductive connection members 37 that are provided between the plurality of first substrate pads 23 and the plurality of chip pads 33, respectively. However, it may be understood that the present inventive concepts are not limited thereto. Accordingly, the connection method between the semiconductor chip and the package substrate may vary.

Although only a few chip pads are illustrated in the figures, it is to be understood that this is merely an example and that the present inventive concepts are not limited thereto. Accordingly, the number, size, arrangement, and shape of the chip pads may vary. In addition, although only one semiconductor chip is illustrated in the figures, this is also merely an example, and the present inventive concepts are not limited thereto. Accordingly, the semiconductor package may include a semiconductor device having a plurality of semiconductor chips.

In some example embodiments, the molding member 40 may have a first surface (e.g., an upper surface) 40a and a second surface (e.g., a lower surface) 40b opposite to the first surface 40b. For example, the first surface 40a may be an upper surface that is in contact with the transparent layer 120, and the second surface 40b may be a lower surface that is in contact with the first surface 21a of the package substrate 21. For example, the molding member 40 may include an epoxy molding compound (EMC). For example, the molding member 40 may not include temperature-sensitive materials that assist in the discoloration of the molding member 40. However, the present inventive concepts are not limited thereto, and the molding member 40 may include the temperature-sensitive materials.

The molding member 40 may include a first marking portion MP1 having a plurality of first marking patterns PA1 that are at least partially exposed from the first surface 40a. For example, the first marking portion MP1 may include machine-recognizable two-dimensional codes such as a product serial number including a plurality of letters and numbers representing information of the semiconductor package, and/or a quick response code (QR code). For example, referring again to FIG. 3, the first marking portion MP1 may include a plurality of first marking patterns PA1 representing a serial number such as ‘ABC 111’. However, it is to be understood that the present inventive concepts are not limited thereto. Accordingly, the shape, arrangement, number, and/or size of the first marking portion may vary.

For example, each of the plurality of first marking patterns PA1 may be a structure in which the molding member 40 is carbonized and partially discolored. Each of the plurality of first marking patterns PA1 may have a first depth H1 in a vertical direction.

In some example embodiments, the transparent layer 120 may be provided on the first surface 40a of the molding member 40. For example, the transparent layer 120 may include a transparent material. In addition, the transparent layer may include a thermosetting material. The transparent layer may include melamine resin, acrylic resin, polyimide resin, silicon resin, etc.

The transparent layer 120 may cover the plurality of first marking patterns PA1, each of which is partially exposed from the first surface 40a of the molding member 40 so that the plurality of first marking patterns PA1 are provided at fixed positions.

As described above, the semiconductor package 10 may include the package substrate 21, the semiconductor chip 30 stacked on the package substrate 21, the molding member 40 provided on the package substrate 21 to cover the semiconductor chip 30, and the transparent layer 120 provided on the upper surface 40a of the molding member 40.

The molding member 40 may include the first marking portion MP1 having the plurality of first marking patterns PA1 that are at least partially exposed from the upper surface 40a. In addition, the transparent layer 120 may include a transparent material and be disposed on the upper surface 40a of the molding member 40 so as to cover each of the plurality of first marking patterns PA1.

Accordingly, because the transparent layer 120 covers each of the plurality of first marking patterns PA1, the plurality of first marking patterns PA1 may be fixed on the upper surface 40a of the molding member 40. Thus, the visibility of the plurality of first marking patterns PA1 may be increased. Further, the first marking portion MP1 may secure a minimum visibility (e.g., a threshold visibility), while each of the plurality of first marking patterns PA1 may have a relatively small first depth H1. For example, the first depth may be 20 μm or less. For example, the first depth may be within a range from 5 μm to 20 μm.

Hereinafter, a method of manufacturing the semiconductor package 10 of FIG. 1 according to an example embodiment will be described.

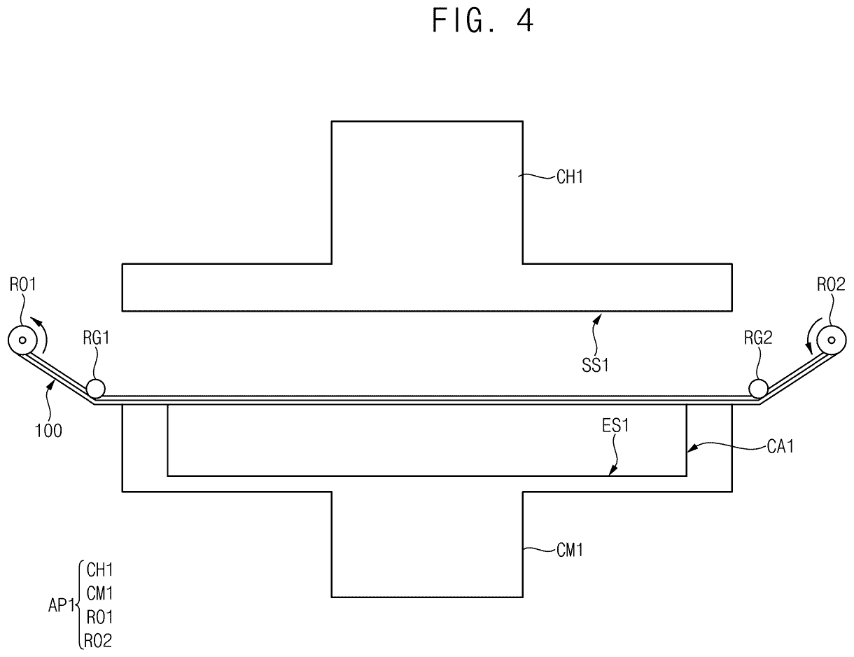

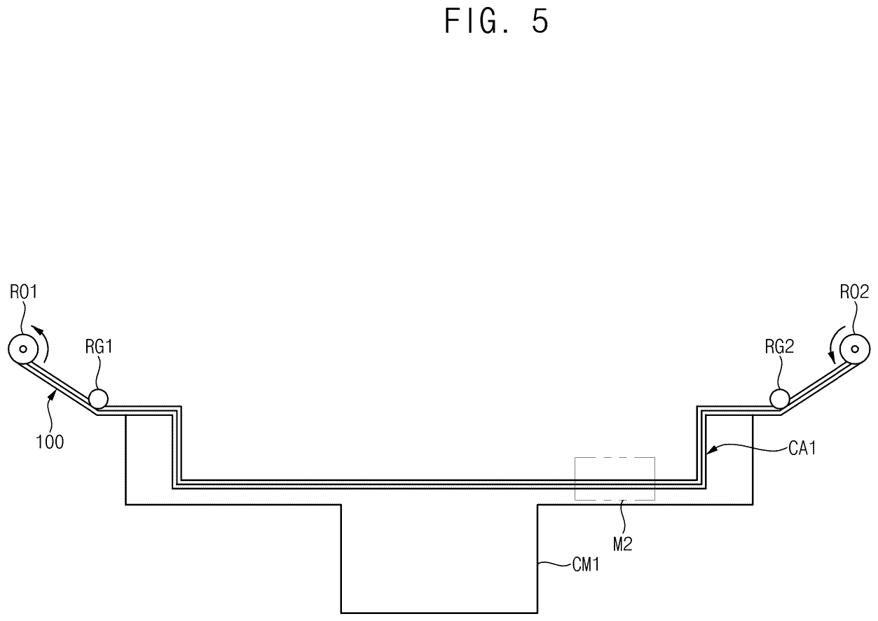

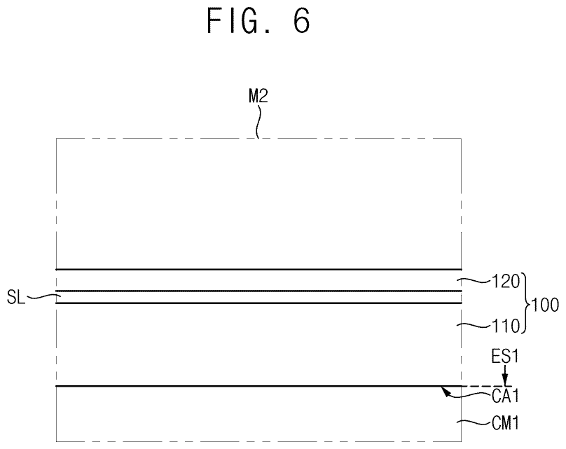

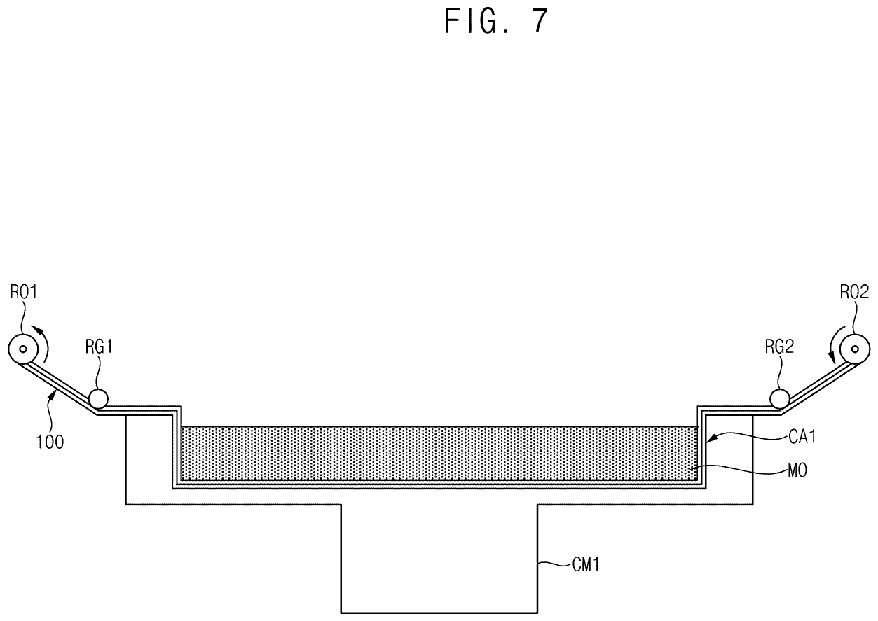

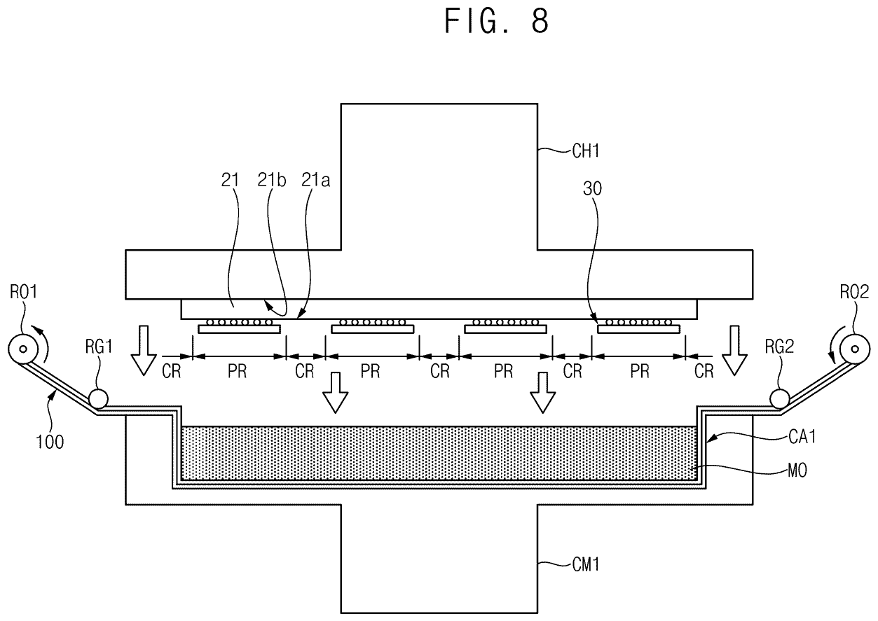

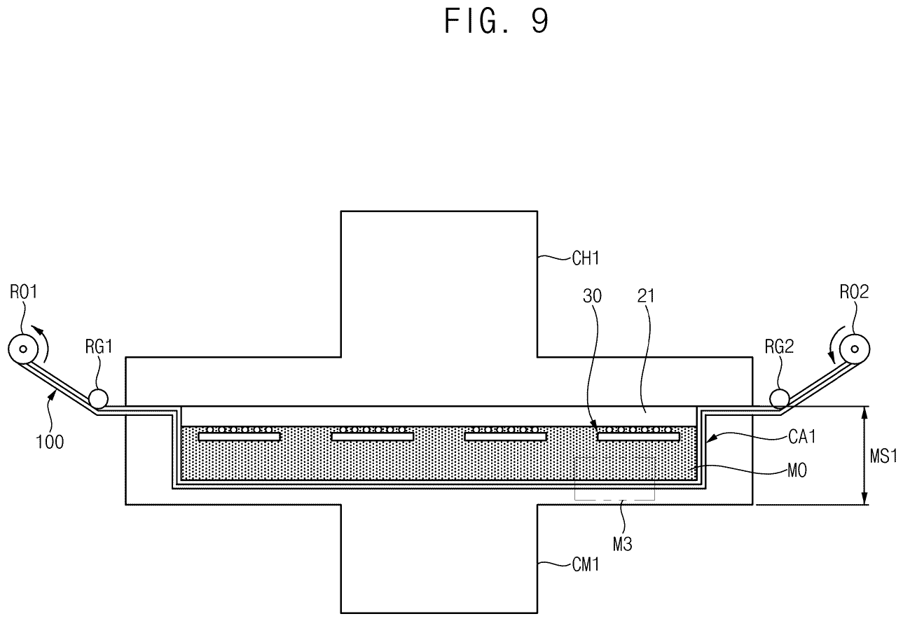

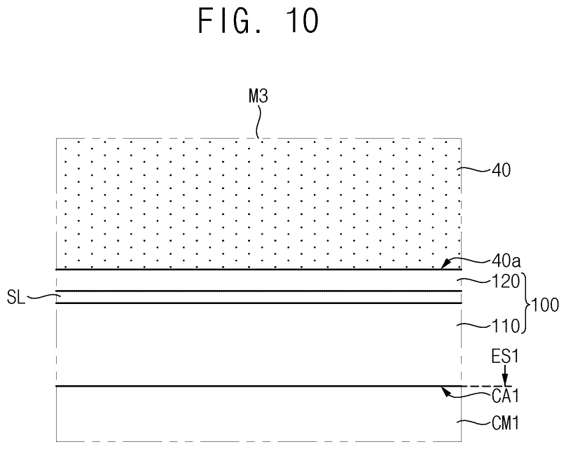

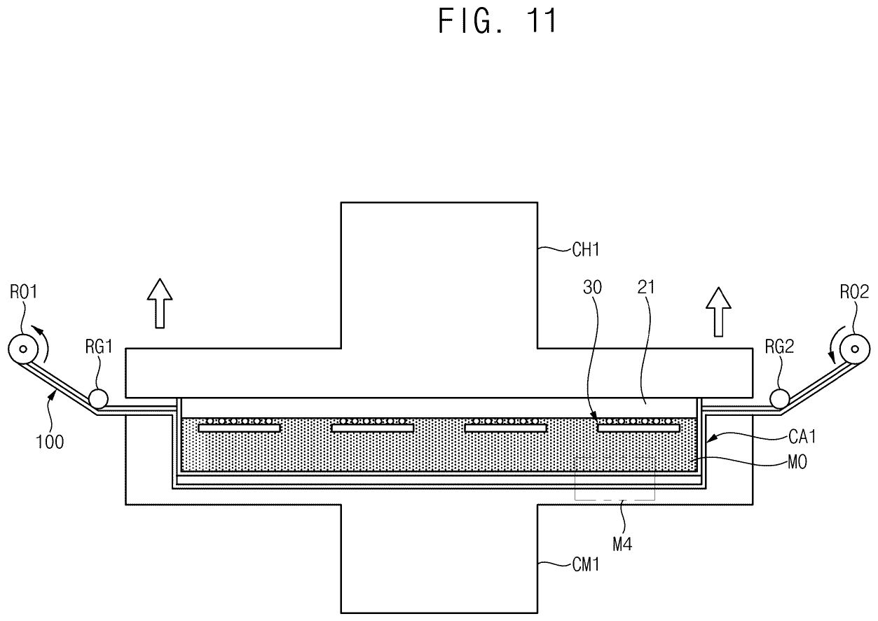

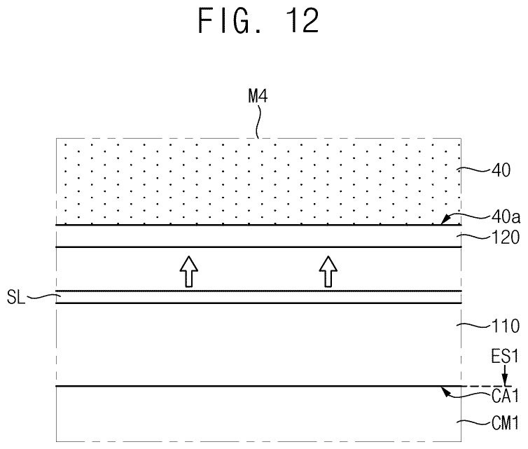

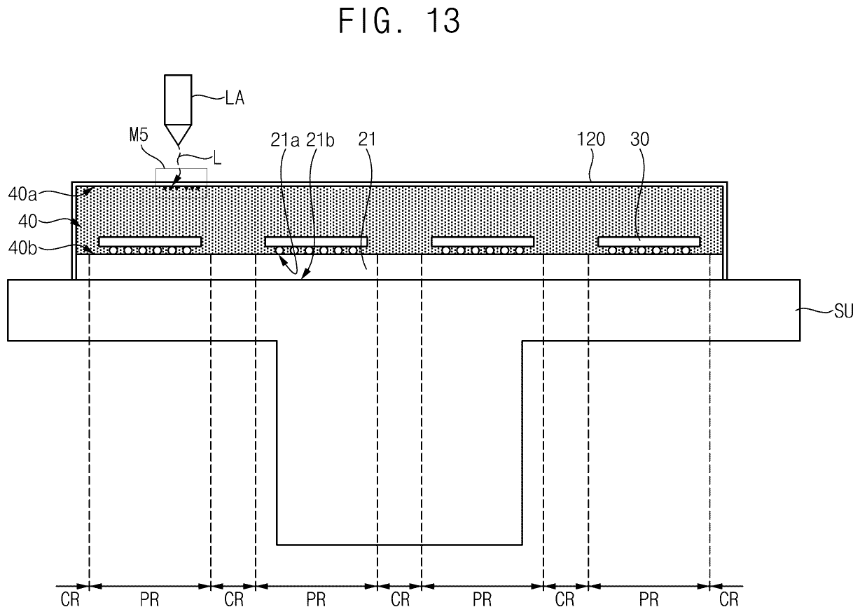

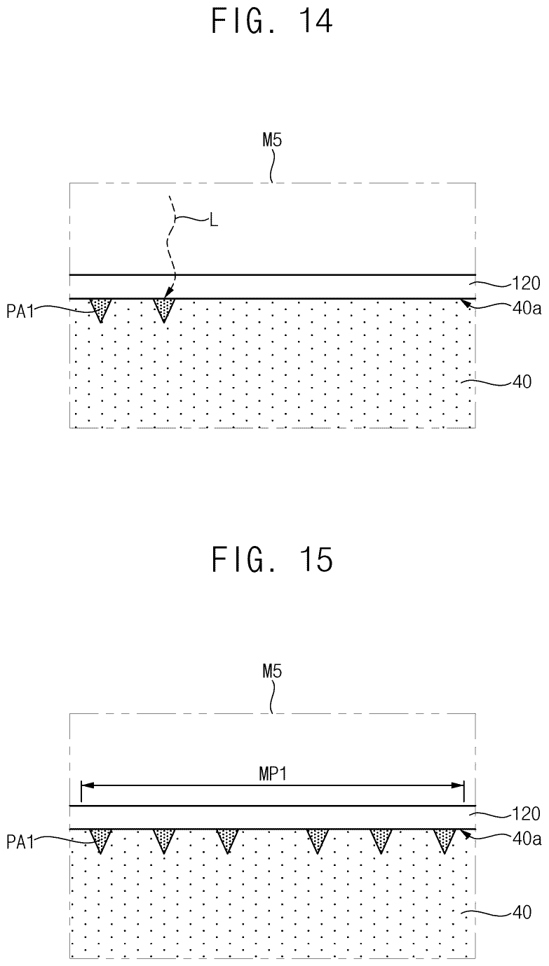

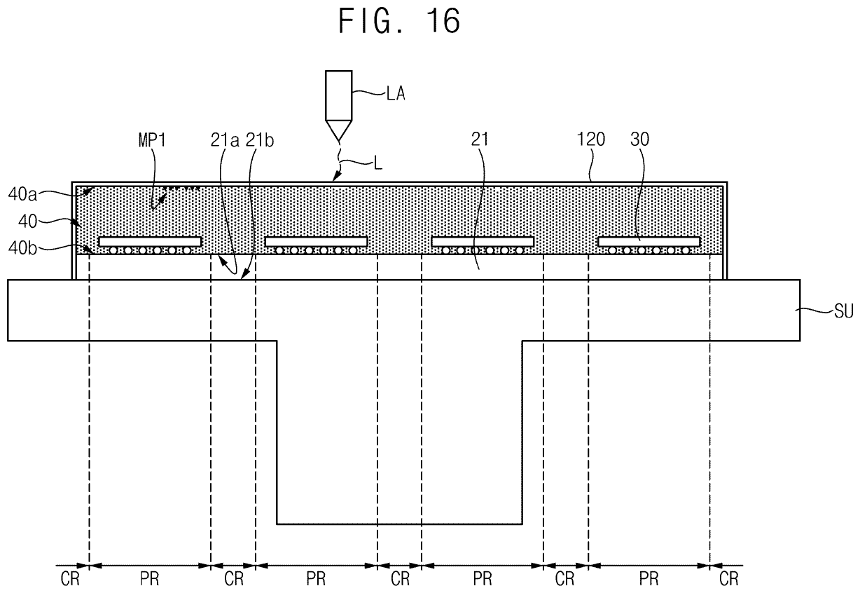

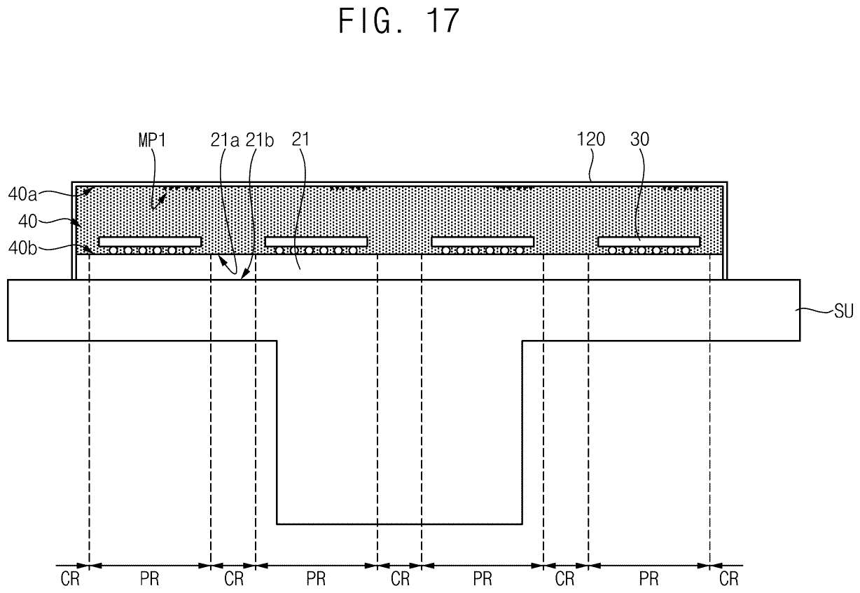

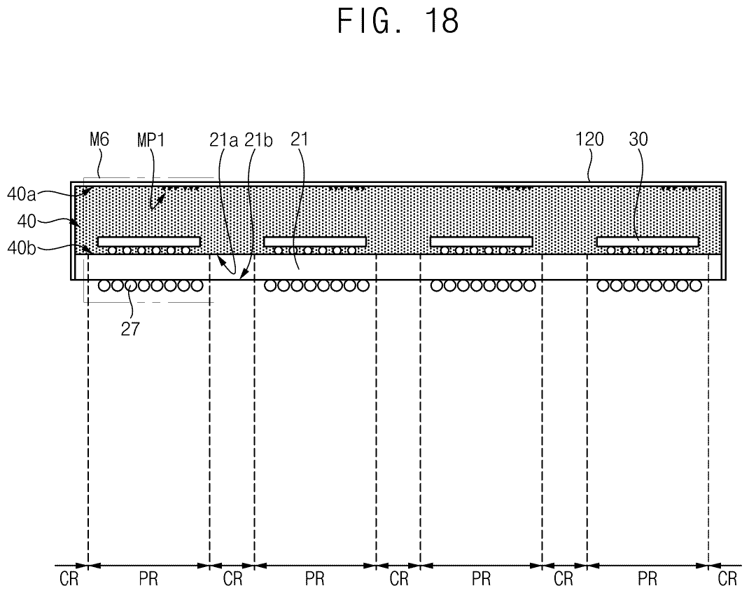

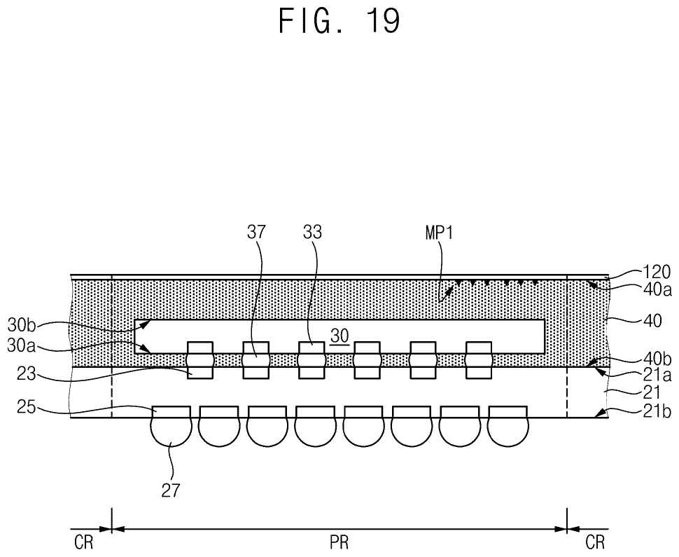

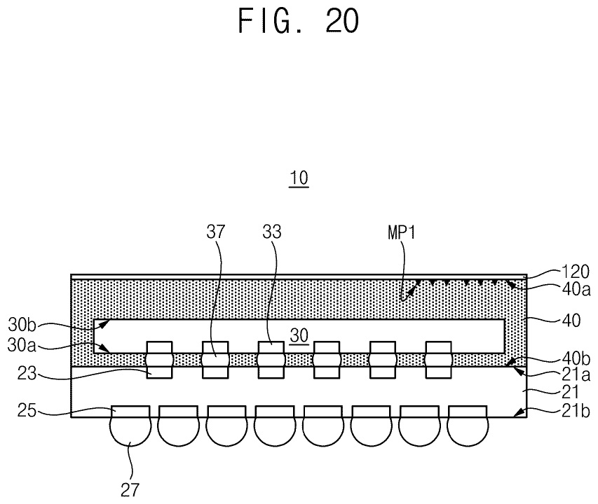

FIG. 4 is a cross-sectional view illustrating a process of providing a protective tape to a molding apparatus in accordance with an example embodiment. FIGS. 5 and 6 are views illustrating a process of attaching the protective tape to the molding apparatus of FIG. 4. FIG. 6 is an enlarged cross-sectional view illustrating portion ‘M2’ in FIG. 5. FIG. 7 is a cross-sectional view illustrating a process of injecting a molding material into the molding apparatus of FIG. 5. FIGS. 8 and 10 are views illustrating a process of immersing semiconductor chips in the molding material of FIG. 7 and then heating the molding material to form a molding member 40. FIG. 10 is an enlarged cross-sectional view illustrating portion ‘M3’ in FIG. 9. FIGS. 11 and 12 are views illustrating a process of separating semiconductor packages covered by the molding member 40 from the molding apparatus of FIG. 9. FIG. 12 is an enlarged cross-sectional view illustrating portion ‘M4’ in FIG. 11. FIGS. 13 to 17 are views illustrating a process of forming first marking portions on the molding member 40 of FIG. 11. FIGS. 14 and 15 are enlarged cross-sectional views illustrating portion ‘M5’ in FIG. 13. FIGS. 18 to 20 are views illustrating processes of attaching external connection members on a package substrate and individualizing semiconductor packages to complete a semiconductor package 10 of FIG. 1. FIG. 19 is an enlarged cross-sectional view illustrating portion ‘M6’ in FIG. 18.

Because the semiconductor package manufactured by the manufacturing method illustrated in FIGS. 4 to 20 is the same as or substantially similar to the semiconductor package described with reference to FIGS. 1 to 3, the same reference numerals are used for the same components, and repeated descriptions of the same components will be omitted.

Referring to FIG. 4, a first protective tape 100 may be provided on a first molding apparatus AP1. For example, the first molding apparatus AP1 may be a compression molding apparatus for performing a molding process to form a molding member 40 on a semiconductor package. In addition, the first protective tape 100 may be a structure for protecting the molding apparatus during the molding process and separating the semiconductor package from the molding apparatus.

In some example embodiments, the first molding apparatus AP1 may include a first mold CM1 having a first cavity CA1 for accommodating a molding material MO therein, and a second mold CH1 having a first support surface SS1 for holding a semiconductor device. For example, the first cavity CA1 may have a first exposed surface ES1 facing upward, and the first support surface SS1 may face downward so as to oppose the first exposed surface ES1. In addition, the first molding apparatus AP1 may further include a plurality of rollers RO1 and RO2 for supplying and collecting the first protective tape 100, and a plurality of roller guides RG1 and RG2 for guiding a movement path of the first protective tape 100.

For example, the first protective tape 100 may extend from the first roller RO1 to the second roller RO2 so as to cover an upper portion of the first cavity CA1. For example, the first roller may be a supply roller, and the second roller may be a collection roller. The plurality of roller guides RG1 and RG2 may guide the movement path of the first protective tape 100 so that the first protective tape 100 comes into contact with the first mold CM1.

As illustrated in FIGS. 5 and 6, the first protective tape 100 may be attached to the first mold CM1 so as to cover the first exposed surface ES1 of the first cavity CA1. For example, the first mold CM1 may attach the first protective tape 100 onto the first exposed surface ES1 of the first cavity CA1 using a vacuum adsorption manner.

In some example embodiments, the first protective tape 100 may include a release film 110 and a transparent layer 120 sequentially stacked on the first cavity CA1. For example, the release film 110 may include a plurality of layers (not shown). For example, the release film may include multiple layers including materials such as polyamide (PA), polyethylene terephthalate (PET), anti-static polymer (AS) for electrostatic protection, etc. In addition, the release film may include a release layer containing a silicon resin. For example, the transparent layer may include melamine resin, acrylic resin, polyimide resin, silicon resin, etc. However, it is understood that the present inventive concepts are not limited thereto. Accordingly, the materials of the release film and the transparent layer may vary.

The release film 110 may include a strip layer SL as a release layer that is in contact with the transparent layer 120. For example, the strip layer SL may be a layer configured to selectively bond to the transparent layer. At room temperature, the strip layer may be bonded to the transparent layer. When the strip layer is heated above a desired (or alternatively, predetermined) temperature during the molding process, the bonding between the strip layer and the transparent layer may weaken. Accordingly, the transparent layer may be relatively easily separated from the release film by the strip layer.

For example, the first protective tape 100 may be attached to the first mold CM1 such that the release film 110 contacts the first exposed surface ES1 of the first cavity CA1, and the transparent layer 120 faces the first support surface SS1 of the second mold CH1

As illustrated in FIG. 7, a molding material MO may be filled into the first cavity CA1 covered by the first protective tape 100. For example, the molding material MO may include an epoxy molding compound (EMC). The molding member 40, which will be formed by curing the molding material MO to be described later, may not include temperature-sensitive materials that assist in discoloration of the molding member 40. However, the present inventive concepts are not limited thereto, and the molding member 40 may include the temperature-sensitive materials.

Referring to FIGS. 8 to 10, a package substrate 21 on which a plurality of semiconductor chips including a semiconductor chip 30 are mounted may be fixedly held on the first support surface SS1 of the second mold CH1, and the second mold CH1 may be moved toward the first mold CM1 so that the plurality of semiconductor chips are immersed in the molding material MO. Then, the molding material MO may be heated to be cured, to form a molding member 40.

The second mold CH1 may move downward to contact the first mold CM1, to provide a first molding space MS1 defined by the first support surface SS1 of the second mold CH1 and the first cavity CA1 of the first mold CM1. For example, the package substrate 21 on which the plurality of semiconductor chips are mounted may be immersed in the molding material MO within the first molding space.

An upper surface 40a of the molding member 40 may be bonded to the transparent layer 120 of the protective tape 100. For example, because the molding material MO is cured during the molding process, the molding member 40 may be bonded to the package substrate 21 and the transparent layer 120. In addition, the strip layer SL of the release film 110 may be heated during the molding process, to weaken or lose the bonding strength with the transparent layer 120.

For example, the package substrate 21 may include a plurality of package regions PR and a cutting region CR surrounding the plurality of package regions PR. The plurality of semiconductor chips may be mounted on the package regions, respectively. The cutting region may be an area to be removed by a cutting process to be described later, in order to individualize the semiconductor packages.

Referring to FIGS. 11 and 12, the second mold CH1 may be moved vertically away from the first mold CM1 so that the transparent layer 120 bonded to the molding member 40 and the package substrate 21 may be separated from the first mold CM1 and the release film 110.

For example, during the molding process, the bonding strength between the strip layer SL of the release film 110 and the transparent layer 120 may decrease, while the bonding strength among the transparent layer 120, the molding member 40, and the package substrate 21 may increase. Accordingly, the transparent layer 120, the molding member 40, and package substrate 21 may be easily separated from the release film 110 by moving the second mold CH1.

Referring to FIGS. 13 to 17, light L may be irradiated onto the molding member 40 to form a plurality of marking portions including a first marking portion MP1 by using a laser apparatus LA.

For example, the separated assembly of the package substrate 21, the molding member 40, and transparent layer 120 may be placed on a support member SU. The package substrate 21 may be arranged on the support member SU such that the transparent layer 120 faces upward.

The laser apparatus LA may be moved in a horizontal direction while irradiating the light L onto the transparent layer 120. The light L may pass through the transparent layer and then may be focused on the upper surface 40a of the molding member 40. The molding member 40 may be at least partially carbonized to forming a plurality of first marking patterns PA1 that are at least partially exposed from the upper surface 40a of the molding member 40. For example, the first marking portion MP1 including the plurality of first marking patterns PA1 may be positioned on the package region PR. For example, the first marking portion MP1 may include a plurality of characters and/or numbers such as a product serial number or a machine-recognizable two-dimensional code such as a quick response (QR) code, representing information of the semiconductor package.

Because the transparent layer 120 covers the upper surface 40a of the molding member 40, the carbonized molding materials generated when forming the plurality of first marking patterns PA1 may be fixedly trapped between the transparent layer 120 and the molding member 40. Accordingly, the visibility of the first marking portion may be increased. In addition, a marking depth desired to ensure the visibility may be relatively reduced. Further, the visibility may be secured by using a laser with relatively low power.

In addition, because no dust is generated due to the carbonization of the molding material, marking defects caused by dust may be reduced or eliminated, and a separate cleaning process to remove dust may not be desired, thereby improving process efficiency.

Referring to FIGS. 18 to 20, the bonded assembly of the package substrate 21, the molding member 40, and the transparent layer 120 may be separated from the support member SU, a plurality of external connection members 27 may be attached onto second substrate pads 27 of the package substrate 21, and the package substrate 21 may be cut along the cutting region CR to complete individualized semiconductor packages 10.

Hereinafter, a method of manufacturing the semiconductor package 10 of FIG. 1 according to an example embodiment will be described.

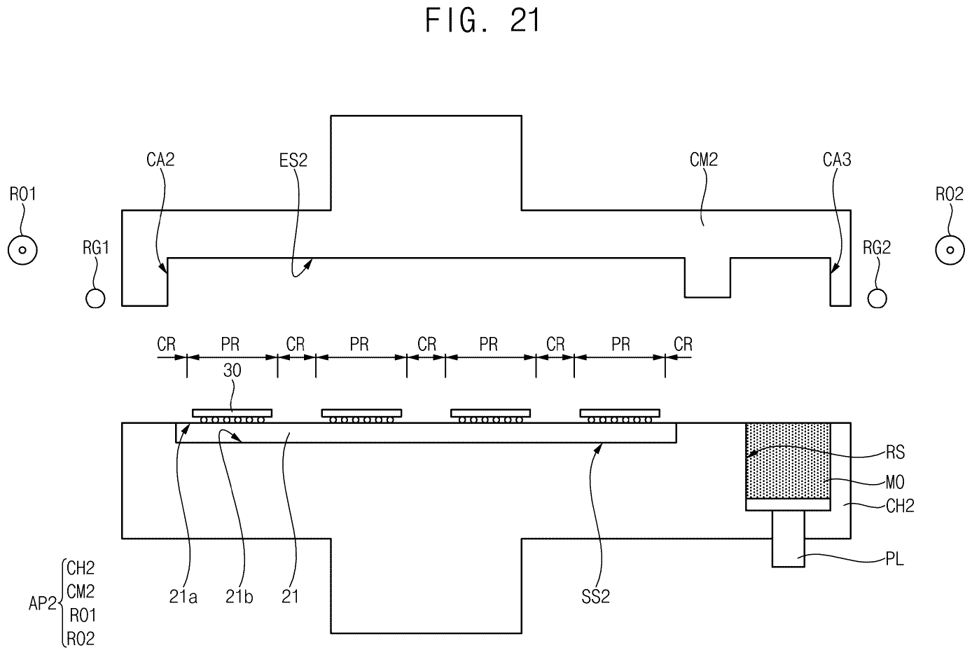

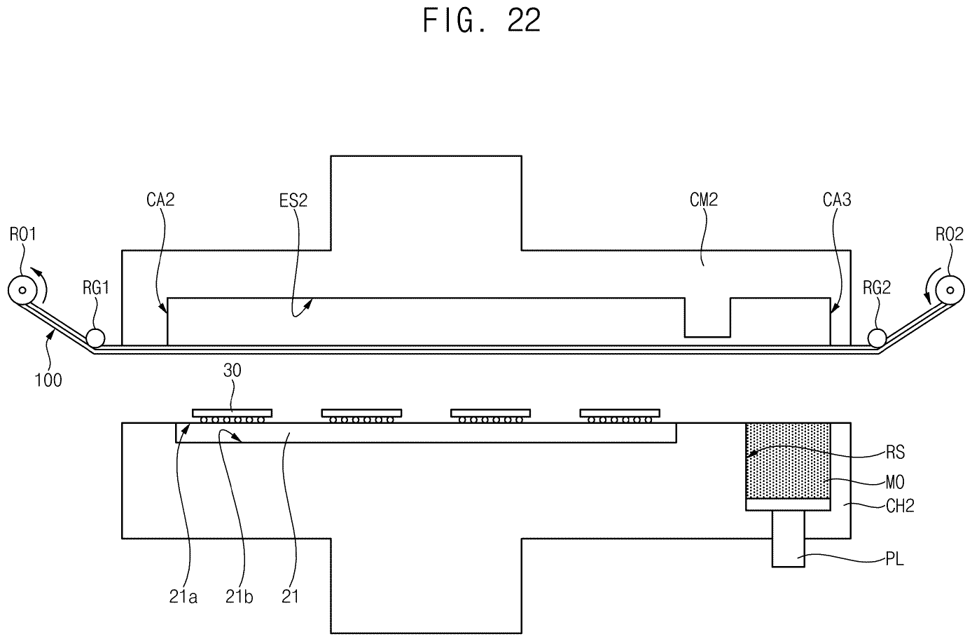

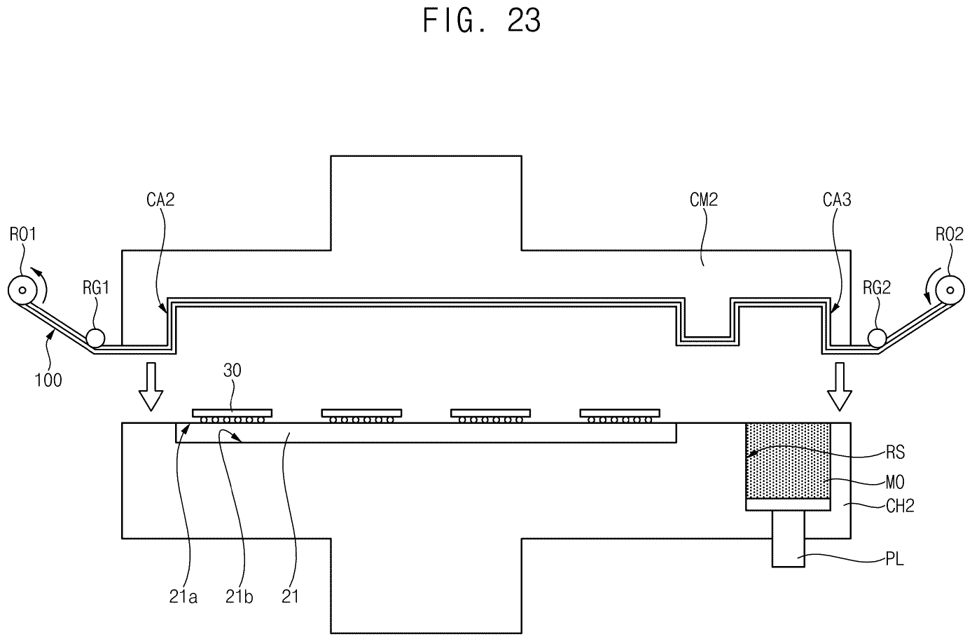

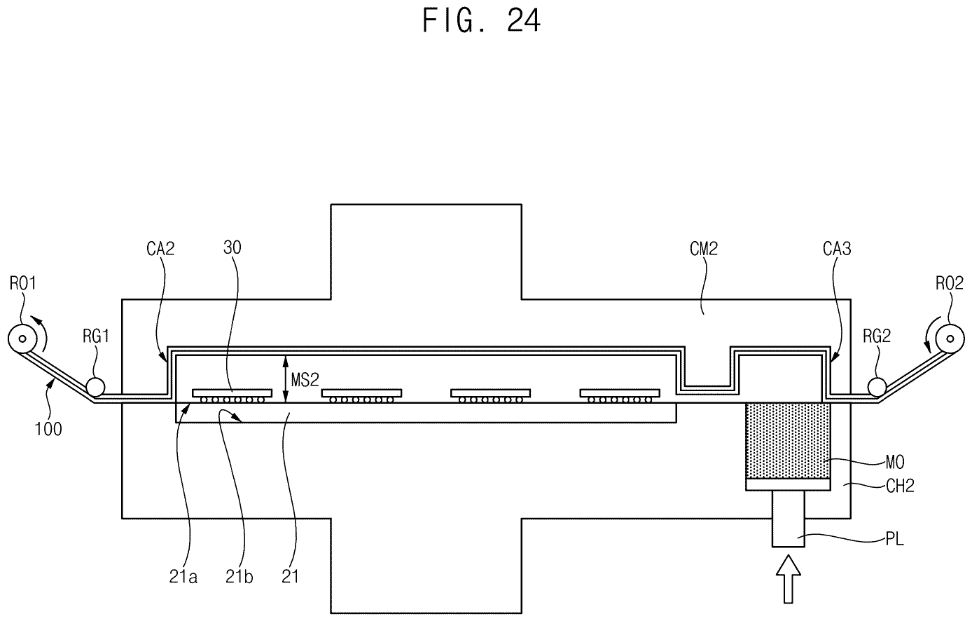

FIG. 21 is a cross-sectional view illustrating a molding apparatus in accordance with an example embodiment. FIGS. 22 and 23 are views illustrating a process of attaching a protective tape onto the molding apparatus. FIGS. 24 and 25 are views illustrating a process of injecting a molding material into a molding space and heating the molding material to form a molding member.

Because the semiconductor package manufactured by the manufacturing method illustrated in FIGS. 21 to 25 is the same as or substantially similar to the semiconductor package described with respect to FIGS. 1 to 3, the same reference numerals are used for the same components, and repeated descriptions of the same components will be omitted.

Referring to FIG. 21, a second molding apparatus AP2 may be provided, and a package substrate 21 on which a plurality of semiconductor chips 30 are mounted may be loaded into the second molding apparatus AP2. For example, the second molding apparatus AP2 may be a transfer molding apparatus for forming a molding member on a semiconductor package.

In some example embodiments, the second molding apparatus AP2 may include a third mold CM2 having a second cavity CA2 and a third cavity CA3, and a fourth mold CH2 having a second support surface SS2 for fixedly holding a semiconductor device. For example, the second cavity CA2 may have a second exposed surface ES2 facing downward, and the second support surface SS2 may face upward to face the second exposed surface ES2.

In addition, the second molding apparatus AP2 may further include a plurality of rollers RO1 and RO2 for supplying and collecting a protective tape, and a plurality of roller guides RG1 and RG2 for adjusting a movement path of the protective tape.

The fourth mold CH2 of the second molding apparatus AP2 may include a reservoir space RS for storing a molding material MO, and may include a plunger PL provided in the reservoir space RS to inject the molding material MO.

For example, the package substrate 21 on which a plurality of semiconductor chips are mounted may be placed on the second support surface SS2 of the fourth mold CH2. In addition, the third mold CM2 may be aligned with the fourth mold CH2 such that the second cavity CA2 faces the package substrate 21 and the third cavity CA3 faces the reservoir space RS.

Referring to FIGS. 22 and 23, a first protective tape 100 may be provided on the third mold CM2, and the first protective tape 100 may be attached to the third mold CM2 so as to cover the second exposed surface ES2 of the second cavity CA2.

Because the semiconductor package manufactured by the manufacturing processes illustrated in FIGS. 21 to 25 is the same as or substantially similar to the semiconductor package described with reference to FIGS. 4 to 20, the same reference numerals are used for the same components, and repeated descriptions of the same components will be omitted.

For example, the second protective tape 100 may extend from a first roller RO1 to a second roller RO2 so as to cover a bottom portion of the second cavity CA2 and the third cavity CA3. For example, the first roller RO1 may be a supply roller, and the second roller RO2 may be a collection roller. A plurality of roller guides RG1 and RG2 may adjust the path of the second protective tape 100 so that the first protective tape 100 contacts the third mold CM2.

The first protective tape 100 may be attached onto the third mold CM2 so as to cover the second cavity CA2 and the third cavity CA3. For example, the third mold CM2 may use a vacuum suction method to attach the first protective tape 100 onto the second cavity CA2 and the third cavity CA3

Referring to FIGS. 24 and 25, the third mold CM2 may be moved toward the fourth mold CH2 to provide a second molding space MS2 defined by the second cavity CA2 and the third cavity CA3 of the third mold CM2 and the fourth mold CH2. Then, the plunger PL may be moved to inject the molding material MO into the second molding space MS2, and the molding material MO may be heated and cured to form the molding member 40.

Then, processes the same as or similar to the processes describe with reference to FIGS. 11 to 20 may be performed to complete the semiconductor package 10.

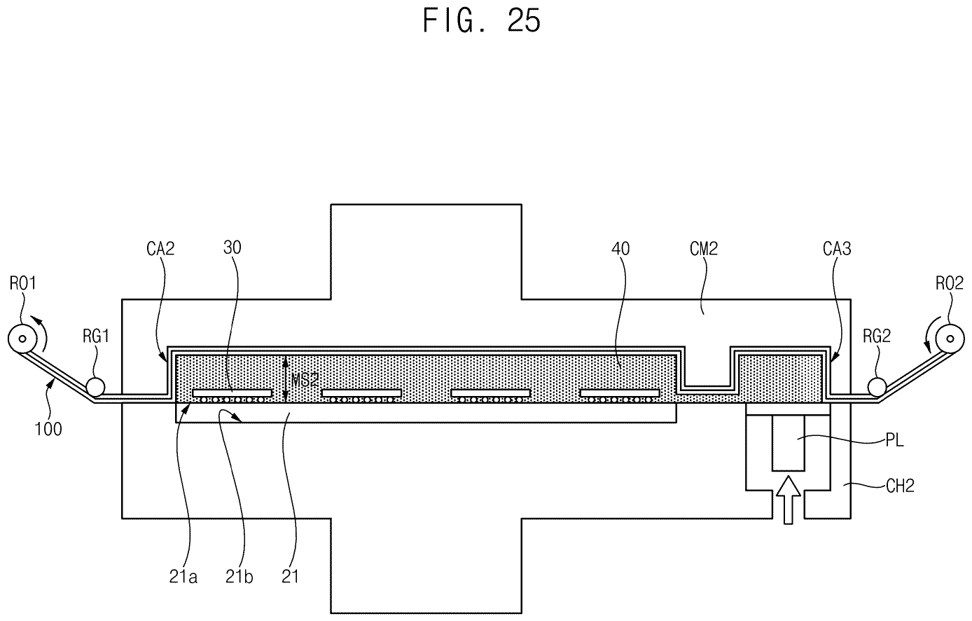

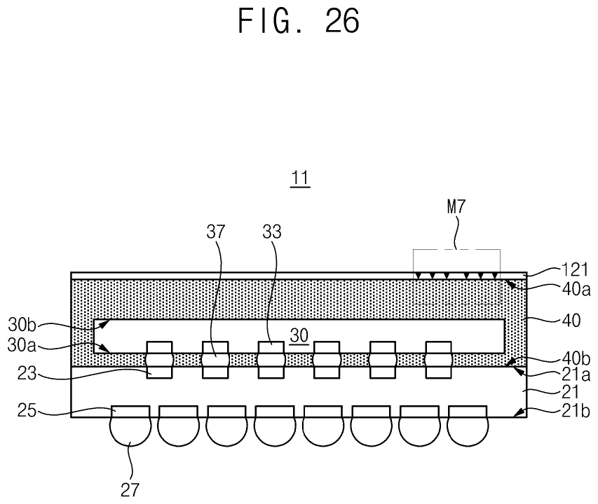

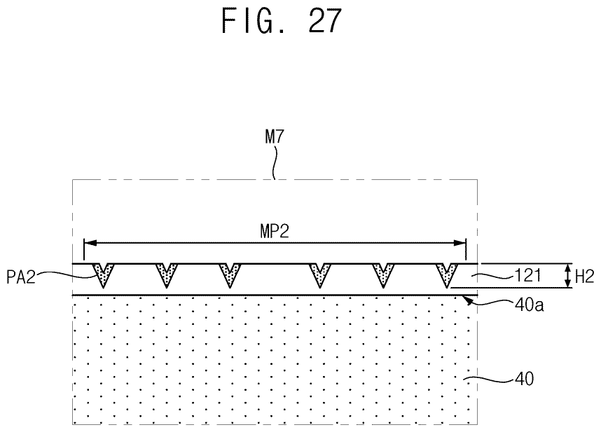

FIG. 26 is a cross-sectional view illustrating a semiconductor package in accordance with an example embodiment. FIG. 27 is an enlarged cross-sectional view illustrating portion ‘M7’ in FIG. 26.

The semiconductor package 11 illustrated in FIGS. 26 and 27 is the same as or substantially similar to the semiconductor package described with respect to FIGS. 1 to 3, except for a first patterned marking layer 121 and a second marking portion MP2. Therefore, the same components are denoted by the same reference numerals, and repeated descriptions of the same components are omitted.

Referring to FIGS. 26 and 27, a semiconductor package 11 may include a package substrate 21, a semiconductor chip 30 stacked on the package substrate 21, a molding member 40 provided on the package substrate 21 to cover the semiconductor chip 30, and a first patterned marking layer 121 covering an upper surface 40a of the molding member 40 and including a metal material. For example, the first patterned marking layer 121 may serve as a portion for forming a second marking portion MP2 to be described later. In addition, the first patterned marking layer 121 may function as a heat slug that dissipate heat generated from the semiconductor chip 30 to the outside to improve the heat dissipation characteristics of the semiconductor package.

In some example embodiments, the first patterned marking layer 121 may be provided on the first surface 40a of the molding member 40.

The first patterned marking layer 121 may include a metal material that discolors relatively more easily than the molding member 40. For example, the first patterned marking layer may include metal materials such as aluminum (Al) or titanium (Ti). However, the present inventive concepts are not limited thereto, and the material of the first patterned marking layer may vary.

For example, each of the plurality of second marking patterns MP2 may be a structure in which a portion of the first patterned marking layer is partially discolored by a laser.

The first patterned marking layer 121 may include a second marking portion MP2 having a plurality of second marking patterns PA2 that are at least partially exposed from an upper surface of the first patterned marking layer 121.

For example, the second marking portion MP2 may include machine-readable two-dimensional codes such as a product serial number including a plurality of letters and/or numbers representing information of the semiconductor package, or a quick response code (QR code). However, the present inventive concepts are not limited thereto. Accordingly, the shape, arrangement, number, and/or size of the second marking portion may vary.

As described above, the semiconductor package 11 may include the first patterned marking layer 121 covering the upper surface 40a of the molding member 40.

The first patterned marking layer 121 may include the second marking portion MP2 having the plurality of second marking patterns PA2 that are at least partially exposed from the upper surface of the first patterned marking layer 121.

Thus, the first patterned marking layer 121 may release heat generated from the semiconductor chip 30 to the outside, thereby improving the heat dissipation characteristics of the semiconductor package. Additionally, because the first patterned marking layer may include a metal material that is relatively easily discolored, the visibility of the plurality of second marking patterns PA2 may be increased. Furthermore, the second marking portion MP2 may secure a minimum visibility (e.g., a threshold visibility) while each of the plurality of second marking patterns PA2 may have a relatively small second depth H2. For example, the second depth may be 20 μm or less. For example, the second depth may be in a range from 5 μm to 20 μm. Also, for example, the second depth may be approximately 1 μm.

Hereinafter, a method of manufacturing the semiconductor package 11 of FIG. 26 according to an example embodiment will be described.

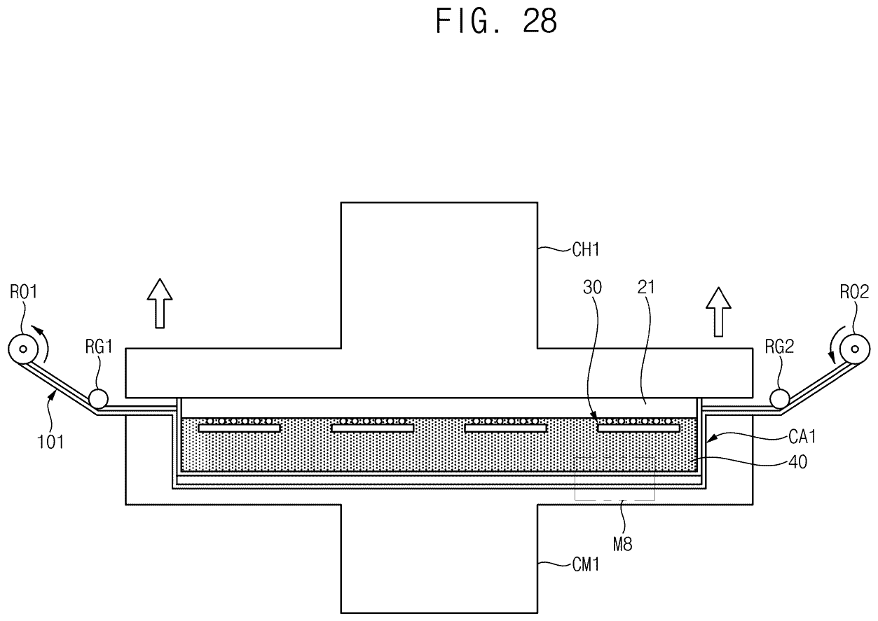

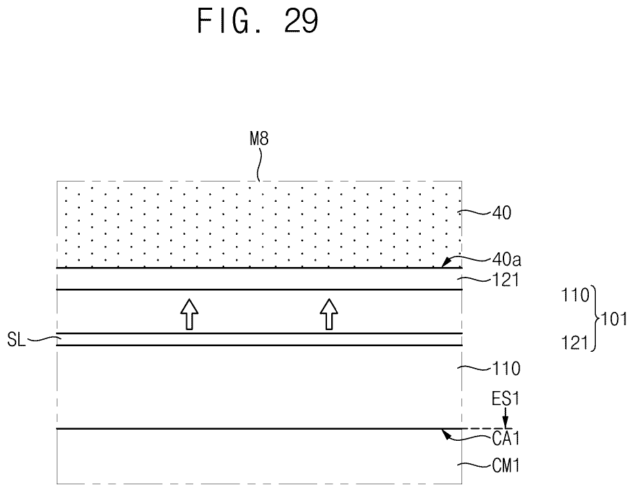

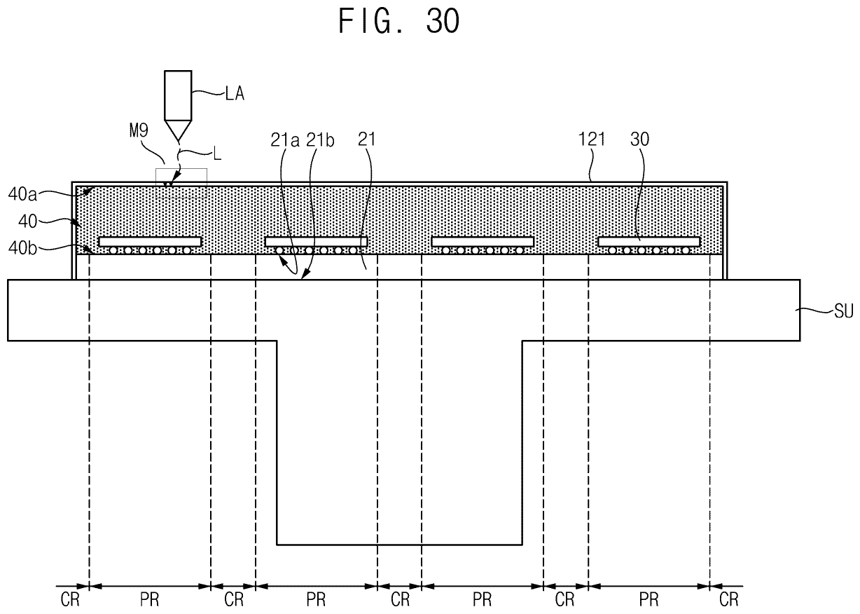

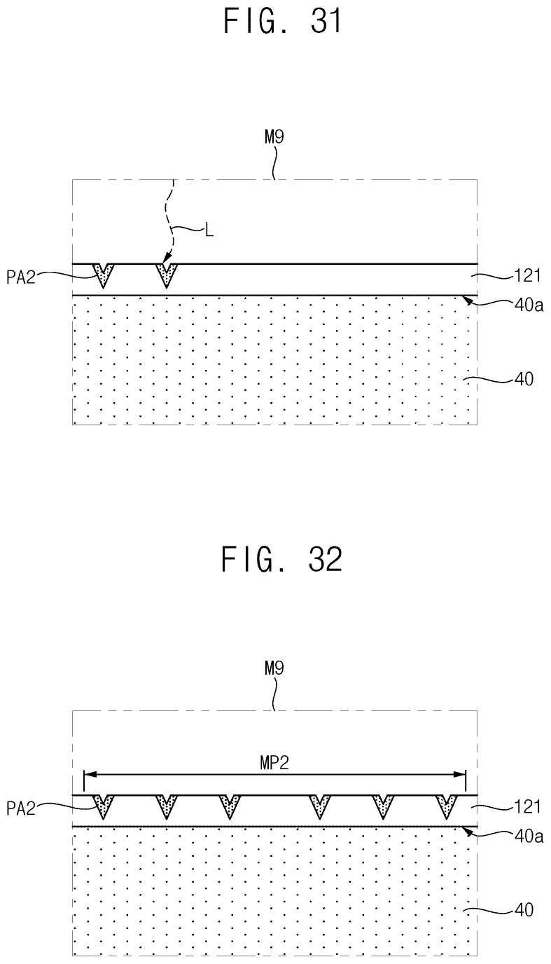

FIGS. 28 and 29 are views illustrating a process of separating semiconductor packages covered by a molding member from a molding apparatus. FIG. 29 is an enlarged cross-sectional view illustrating portion ‘M8’ in FIG. 28. FIGS. 30 to 32 are views illustrating a process of forming second marking portions on the molding member of FIG. 28. FIGS. 31 and 32 are enlarged cross-sectional views illustrating portion ‘M9’ in FIG. 32.

The semiconductor package manufactured by the manufacturing processes illustrated in FIGS. 28 to 30 is the same as or substantially similar to the semiconductor package described with respect to FIGS. 26 and 27. Therefore, the same components are denoted by the same reference numerals, and repetitive descriptions of the same components are omitted.

Processes the same as or substantially similar to the processes described with reference to FIGS. 4 to 10 may be performed to immerse a plurality of semiconductor chips in a molding material, and heat the molding material to form a bonded assembly of a first patterned marking layer 121, a molding member 40, and a package substrate 21. Repetitive descriptions of the processes the same as or substantially similar to the processes described with reference to FIGS. 4 to 10 are omitted.

Referring to FIGS. 28 and 29, the second mold CH1 may be moved vertically away from the first mold CM1 to separate the first patterned marking layer 121 bonded to the molding member 40 and package substrate 21 from the first mold CM1 and a second protective tape 101.

In some example embodiments, the second protective tape 101 may include a release film 110 and a first patterned marking layer 121 sequentially stacked on the second cavity CA2. For example, the first patterned marking layer 121 may include a metal material such as aluminum (Al) or titanium (Ti). For example, the release film 110 may include a plurality of layers (not shown). However, the present inventive concepts are not limited thereto. Accordingly, the materials of the release film and the first patterned marking layer may vary.

The release film 110 may include a strip layer SL that in contact with the first patterned marking layer 121. For example, the strip layer SL may be a layer configured to selectively bond with the first patterned marking layer 121. At room temperature, the strip layer SL may be bonded to the first patterned marking layer 121. When the strip layer SL is heated above a desired (or alternatively, preset) temperature during the molding process, the bonding between the strip layer SL and the first patterned marking layer 121 may weaken. Accordingly, the first patterned marking layer 121 may be relatively easily separated from the release film 110 by the strip layer SL.

For example, the bonding force between the release layer SL of the release film 110 and the first patterned marking layer 121 may decrease during the molding process, while the bonding force between the first patterned marking layer 121, the molding member 40, and the package substrate 21 may increase during the molding process. Therefore, by moving the second mold CH1, the first patterned marking layer 121, the molding member 40, and the package substrate 21 may be easily separated from the release film 110 of the second protective tape 102.

Referring to FIGS. 31 to 33, light L may be irradiated onto the first patterned marking layer 121 to form a plurality of marking portions including second marking portion MP2 by utilizing a laser apparatus LA.

For example, the separated bonding assembly of the package substrate 21, the molding member 40, and first patterned marking layer 121 may be placed on a support member SU. The package substrate 21 may be placed on the support member SU such that the first patterned marking layer 121 faces upward.

The laser apparatus LA may be moved in a horizontal direction while irradiating the light L onto the first patterned marking layer 121. The first patterned marking layer 121 may be at least partially discolored to form the plurality of second marking patterns PA2 that are at least partially exposed from the upper surface of the first patterned marking layer 121. For example, the second marking portion MP2, including the plurality of second marking patterns PA2, may be positioned on the package region PR. For example, the second marking portion MP2 may include machine-readable two-dimensional codes, such as a product serial number including a plurality of letters and/or numbers representing information of the semiconductor package, or a quick response code (QR Code).

The first patterned marking layer 121 may include a metal material that is relatively easily discolored compared to the molding member 40. For example, the first patterned marking layer may include metal materials such as aluminum (Al) or titanium (Ti). However, the present inventive concepts are not limited thereto, and the material of the first patterned marking layer may vary.

Accordingly, because the first patterned marking layer 121 includes a metal material that is relatively easily discolored, the visibility of the plurality of second marking patterns PA2 may be increased. Furthermore, the marking depth desired to secure visibility may be relatively reduced. In addition, visibility may be secured by using a laser with relatively low power.

Processes the same as or similar to the processes described with reference to FIGS. 16 to 20 may be performed to complete the semiconductor package 11.

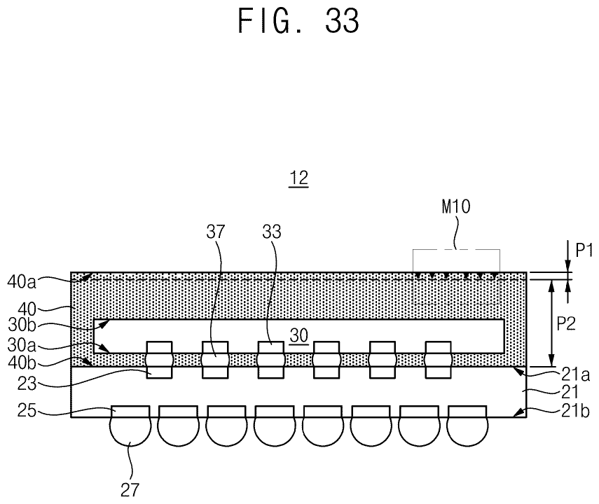

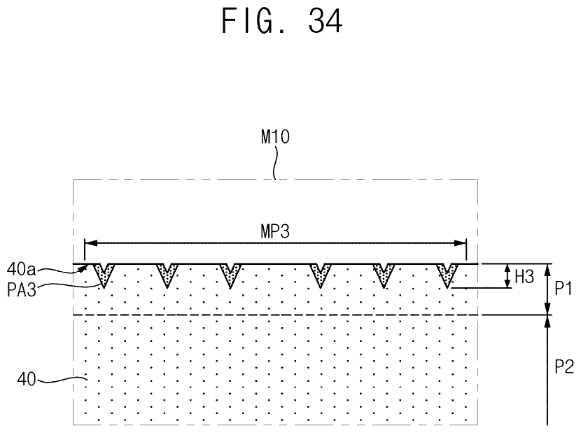

FIG. 33 is a cross-sectional view illustrating a semiconductor package 12 in accordance with an example embodiment. FIG. 34 is an enlarged cross-sectional view illustrating portion ‘M10’ in FIG. 33.

The semiconductor package 12 illustrated in FIGS. 33 and 34 is the same as or substantially similar to the semiconductor package described with reference to FIGS. 1 to 3, except for the molding member 40. Accordingly, the same components are designated by the same reference numerals, and repeated descriptions of the same components will be omitted.

Referring to FIGS. 33 and 34, the semiconductor package 12 may include a package substrate 21, a semiconductor chip 30 stacked on the package substrate 21, and a molding member 40 provided on the package substrate 21 to cover the semiconductor chip 30.

In some example embodiments, the molding member 40 may include a first surface 40a and a second surface 40b opposite to the first surface 40a. For example, the first surface 40a may be an upper surface that is exposed to the outside, and the second surface 40b may be a lower surface that is in contact with a first surface 21a of the package substrate 21. For example, the molding member 40 may include an epoxy molding compound (EMC). For example, the molding member 40 may include temperature-sensitive materials to assist in discoloration of the molding member.

The molding member 40 may include a first portion P1 including the first surface 40a and a second portion P2 including the second surface 40b. For example, the first portion P1 may contain the temperature-sensitive material and may be a region where a third marking portion MP3 is provided. In addition, the second portion P2 may not contain the temperature-sensitive material and may be a region that covers the semiconductor chip 30.

The molding member 40 may include a third marking portion MP3 having a plurality of third marking patterns PA3 that are provided in the first portion P1 and at least partially exposed from the first surface 40a. For example, the third marking portion MP3 may include machine-readable two-dimensional codes, such as a product serial number comprising a plurality of letters and/or numbers representing information of the semiconductor package, or a quick response (QR) code. However, the present inventive concepts are not limited thereto. Accordingly, the shape, arrangement, number, and/or size of the third marking portion may vary.

For example, each of the plurality of third marking patterns PA3 may be a partially discolored structure formed by carbonization of the molding member 40. Each of the third marking patterns PA3 may have a third depth H3 in a vertical direction.

As described above, the semiconductor package 12 may include the package substrate 21, the semiconductor chip 30 stacked on the package substrate 21, and the molding member 40 provided on the package substrate 21 to cover the semiconductor chip 30.

The molding member 40 may include the first portion P1 having the upper surface 40a, and the first portion P1 may include a temperature-sensitive material. Additionally, the molding member 40 may include the third marking portion MP3 having the plurality of third marking patterns PA3 that are provided within the first portion P1 so as to be at least partially exposed from the upper surface 40a.

Accordingly, because the first portion P1 of the molding member 40 includes a temperature-sensitive material, it may discolor relatively more easily compared to the second portion of the molding member 40. Thus, the visibility of the plurality of third marking patterns PA3 may increase. Furthermore, the third marking portion MP3 may secure a minimum visibility (e.g., a threshold visibility) while each of the plurality of third marking patterns PA3 may have a relatively small third depth H3. For example, the third depth may be 20 μm or less. For example, the third depth may be within a range from 5 μm to 20 μm.

Hereinafter, a method of manufacturing the semiconductor package 12 of FIG. 33 according to an example embodiment will be described.

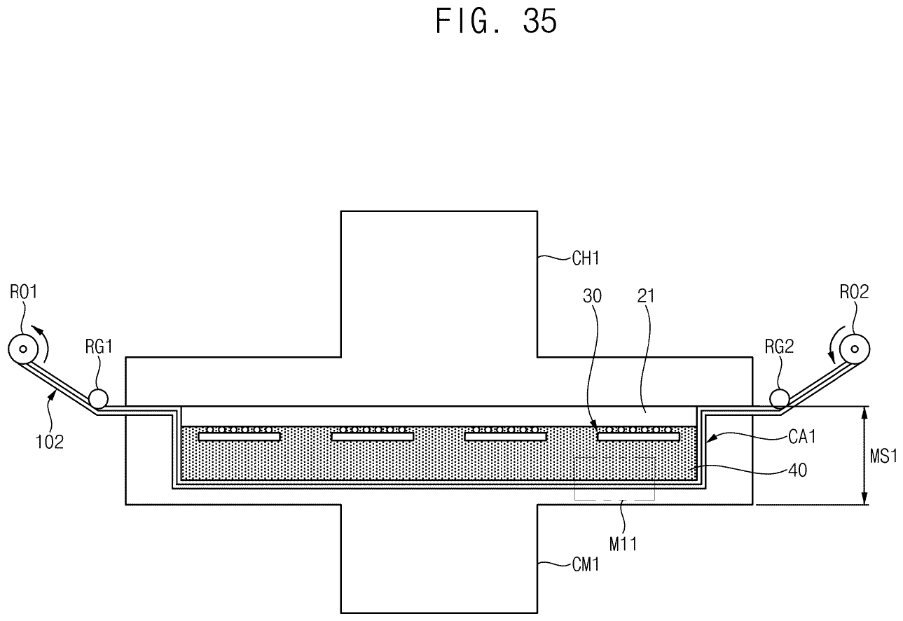

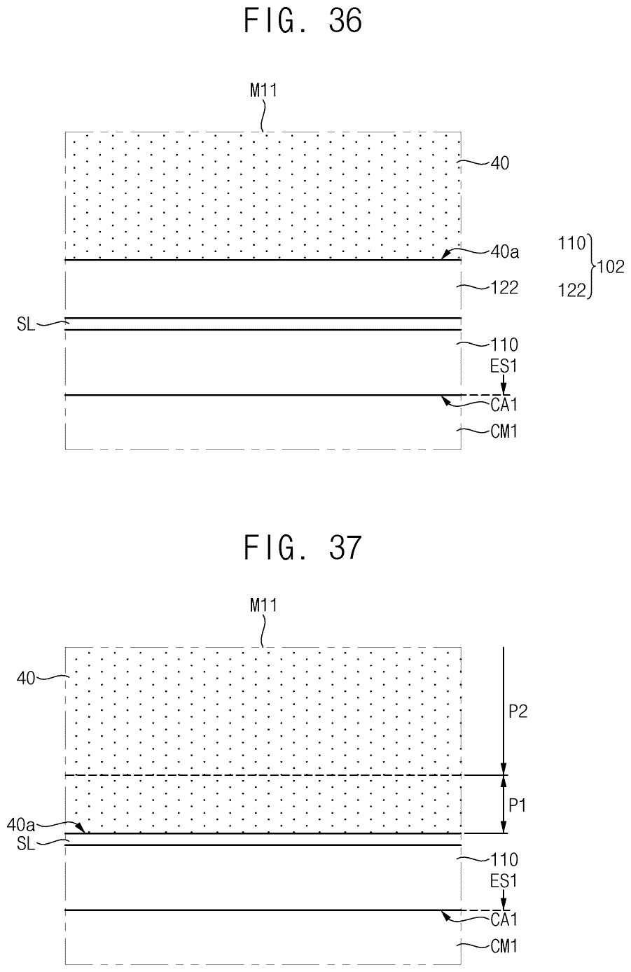

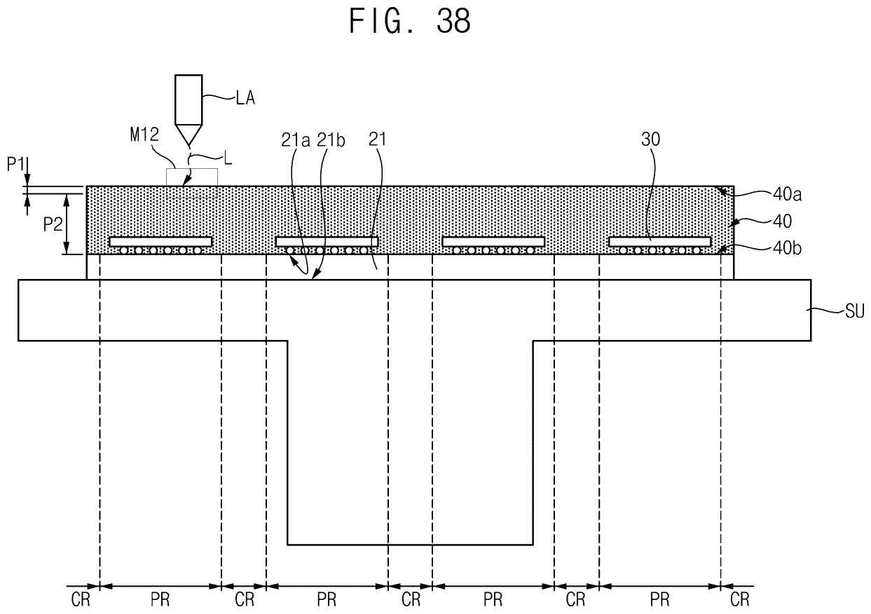

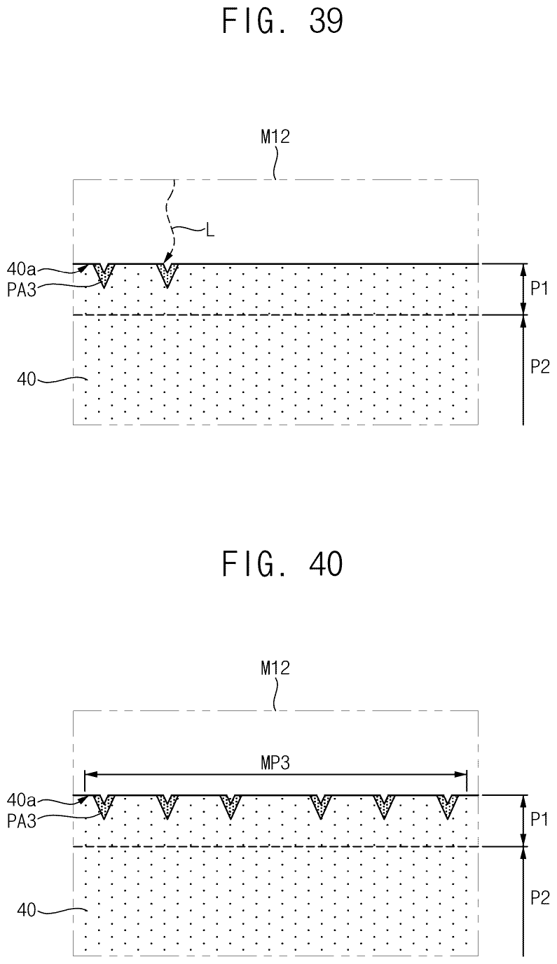

FIGS. 35 to 37 are views illustrating a process of immersing semiconductor chips in a molding material and then heating the molding material to form a molding member. FIGS. 36 and 37 are enlarged cross-sectional views illustrating portion ‘M11’ in FIG. 35. FIGS. 38 to 40 are views illustrating a process of forming third marking portions on the molding member in FIG. 35. FIGS. 39 and 40 are enlarged cross-sectional views illustrating portion ‘M12’ in FIG. 38.

The semiconductor package manufactured by the manufacturing processes illustrated in FIGS. 35 to 40 is the same as or substantially similar to the semiconductor package described with reference to FIGS. 33 and 34. Accordingly, the same components are denoted by the same reference numerals, and redundant descriptions of the same components are omitted.

By performing a process the same as or substantially similar to the process illustrated in FIGS. 4 to 8, a plurality of semiconductor chips may be immersed in the molding material. Redundant descriptions of the process the same as or substantially similar to that illustrated in FIGS. 4 to 8 are omitted.

Referring to FIGS. 35 to 37, a molding material MO in a first molding space MS1 of a molding apparatus may be heated to cure the molding material MO and form a molding member 40.

For example, an upper surface 40a of the molding member 40 may be bonded to a second patterned marking layer 122 of a third protective tape 102. For example, the molding material MO may be cured during the molding process, so the molding member 40 may be bonded to the package substrate 21 and the second patterned marking layer 122. In addition, a strip layer SL of a release film 110 may be heated during the molding process, which may weaken the bonding strength with the second patterned marking layer 122.

In some example embodiments, the third protective tape 102 may include the release film 110 and the second patterned marking layer 122 sequentially stacked on the first cavity CA1. For example, the second patterned marking layer may include temperature-sensitive materials such as titanium dioxide (TiO₂). The release film 110 may include multiple layers (not shown). However, the present inventive concepts are not limited thereto. Accordingly, the materials of the release film and the second patterned marking layer may vary.

The release film 110 may include a strip layer SL that in contact with the second patterned marking layer 122. For example, the strip layer SL may be a layer configured to selectively bond with the second patterned marking layer 122. At room temperature, the strip layer SL may be bonded to the second patterned marking layer 122. When the strip layer SL is heated above a desired (or alternatively, predetermined) temperature during the molding process, the bonding between the strip layer SLand the second patterned marking layer 122 may weaken. Accordingly, the second patterned marking layer 122 may be relatively easily separated from the release film 110 by the strip layer SL.

For example, the second patterned marking layer 122 may be bonded with a portion of the molding material MO to form a first portion P1 of the molding member 40. Therefore, the first portion P1 may include a temperature-sensitive material.

Then, processes the same as or similar to the processes described with reference to FIGS. 11 and 12 may be performed to separate the molding member 40 and the package substrate 21, which are bonded to each other, from the first mold CM1 and the third protective tape 103. Repeated explanations of the process the same as or substantially similar to those illustrated in FIGS. 11 and 12 are omitted.

Referring to FIGS. 38 to 40, a laser apparatus LA may be used to irradiate light L onto the first portion P1 of the molding member 40 to form a plurality of marking portions including a third marking portion MP3.

For example, the separated bonded assembly of the package substrate 21 and the molding member 40 may be placed on a support member SU. The package substrate 21 may be arranged on the support member SU so that the first portion P1 of the molding member 40 faces upward.

The laser apparatus LA may be moved in a horizontal direction while irradiating the light L onto the first portion P1 of the molding member 40. The first portion P1 may be at least partially carbonized to form the plurality of third marking patterns PA3 that are partially exposed from the upper surface 40a of the molding member 40. For example, the third marking portion MP3 including the plurality of third marking patterns PA3 may be positioned on the package region PR. For example, the third marking portion MP3 may include machine-readable two-dimensional codes such as a product serial number comprising a plurality of letters and numbers representing information of the semiconductor package, or a quick response code (QR code).

The first portion P1 of the molding member 40 may include a temperature-sensitive material that is relatively easily discolored. For example, the temperature-sensitive material may include substances such as titanium dioxide (TiO₂). However, the present inventive concepts are not limited thereto, and the temperature-sensitive material may vary.

Accordingly, because the first portion P1 of the molding member 40 includes a temperature-sensitive material, the visibility of the plurality of third marking patterns PA3 may be increased. Furthermore, the marking depth desired to secure visibility may be relatively reduced. In addition, visibility may be secured by using a laser with relatively low power.

Additionally, because the temperature-sensitive material is provided separately from the molding material by the third protective tape 102, there is no need to mix the temperature-sensitive material and the molding material separately, thereby improving the efficiency of the process.

Further, because only the portion of the molding member including the marking pattern includes the temperature-sensitive material, the amount of temperature-sensitive material consumed is relatively reduced, thereby reducing process costs.

Then, processes the same as or similar to the process described with reference to FIGS. 16 to 20 may be performed to complete the semiconductor package 12.

The foregoing is illustrative of example embodiments and is not to be construed as limiting thereof. Although a few example embodiments have been described, those skilled in the art will readily appreciate that many modifications are possible in the above example embodiments without materially departing from the novel teachings and advantages of the present inventive concepts. Accordingly, all such modifications are intended to be included within the scope of example embodiments as defined in the claims.

What is claimed is:

1. A method of manufacturing a semiconductor package, the method comprising:
providing a molding apparatus, the molding apparatus including a first mold having a cavity configured to accommodate a molding material and a second mold configured to fixedly hold a package substrate having at least one semiconductor chip mounted thereon;
attaching a protective tape onto the cavity of the first mold to cover the cavity of the first mold, the protective tape including a release film and a transparent layer that are sequentially stacked;
forming a molding member between the protective tape and the package substrate to cover the at least one semiconductor chip, the molding member being bonded to the transparent layer;
separating the transparent layer bonded to the molding member and the package substrate from the release film of the protective tape; and
irradiating light onto the molding member through the transparent layer to form a marking portion on a bonding surface of the molding member.

2. The method of claim 1, wherein the forming the molding member comprises:
filling the cavity of the first mold with the molding material;
moving the second mold toward the first mold so that the at least one semiconductor chip is covered by the molding material; and
heating the molding material to harden the molding material.

3. The method of claim 1, wherein the forming the molding member comprises:
fixedly holding the package substrate on the second mold so that the at least one semiconductor chip faces the cavity of the first mold;
moving the first mold toward the second mold to provide a molding space defined by the cavity and the second mold;
filling the molding space with the molding material so that the at least one semiconductor chip is covered by the molding material; and
heating the molding material to harden the molding material.

4. The method of claim 1, wherein the transparent layer includes a thermosetting resin.

5. The method of claim 4, wherein the transparent layer includes at least one of melamine resin, acrylic resin, polyimide resin, or silicon resin.

6. The method of claim 1, wherein forming the marking portion includes at least partially carbonizing the molding member by the light.

7. The method of claim 1, wherein the marking portion is in direct contact with the transparent layer and includes a plurality of patterns that represent information of the semiconductor package.

8. The method of claim 1, wherein the release film includes a strip layer whose adhesive strength decreases when the release film is heated above a temperature.

9. The method of claim 1, wherein the molding member includes an epoxy molding compound.

10. The method of claim 9, wherein the molding member includes a temperature-sensitive material for inducing discoloration by the light.

11. A method of manufacturing a semiconductor package, the method comprising:
providing a molding apparatus, the molding apparatus including a first mold having a cavity configured to accommodate a molding material and a second mold configured to fixedly hold a package substrate having at least one semiconductor chip mounted thereon;
attaching a protective tape onto the cavity of the first mold to cover the cavity of the first mold, the protective tape including a release film and a first patterned marking layer of a metal material;
forming a molding member between the protective tape and the package substrate to cover the at least one semiconductor chip, the molding member being bonded to the first patterned marking layer;
separating the first patterned marking layer bonded to the molding member and the package substrate from the release film of the protective tape; and
irradiating light onto the first patterned marking layer to form a marking portion on the first patterned marking layer.

12. The method of claim 11, wherein the forming the molding member comprises:
filling the cavity of the first mold with the molding material;
moving the second mold toward the first mold so that the at least one semiconductor chip is covered by the molding material; and
heating the molding material to harden the molding material.

13. The method of claim 11, wherein the forming the molding member comprises:
fixedly holding the package substrate on the second mold so that the at least one semiconductor chip faces the cavity of the first mold;
moving the first mold toward the second mold to provide a molding space defined by the cavity and the second mold;
filling the molding space with the molding material so that the at least one semiconductor chip is covered by the molding material; and
heating the molding material to harden the molding material.

14. The method of claim 11, wherein the first patterned marking layer includes at least one of aluminum (Al) or titanium (Ti).

15. The method of claim 11, wherein the marking portion is disposed on an exposed surface of the first patterned marking layer and includes a plurality of patterns that represent information of the semiconductor package.

16. The method of claim 11, wherein the release film includes a strip layer whose adhesive strength decreases when the release film is heated above a temperature.

17. The method of claim 11, wherein the molding member includes an epoxy molding compound.

18. A method of manufacturing a semiconductor package, the method comprising:
providing a molding apparatus, the molding apparatus including a first mold having a cavity configured to accommodate a molding material and a second mold configured to fixedly hold a package substrate having at least one semiconductor chip mounted thereon;
attaching a protective tape onto the cavity of the first mold to cover the cavity of the first mold, the protective tape including a release film and a second patterned marking layer including a temperature-sensitive material;
filling the molding material between the protective tape and the package substrate so as to cover the at least one semiconductor chip;
heating the molding material to form a molding member bonded to the second patterned marking layer and the package substrate;
separating the second patterned marking layer bonded to the molding member and the package substrate from the release film of the protective tape; and
irradiating light onto the second patterned marking layer bonded to the molding member to form a marking portion on the second patterned marking layer.

19. The method of claim 18, wherein forming the marking portion includes at least partially carbonizing the second patterned marking layer bonded to the molding member by the light.

20. The method of claim 18, wherein the second patterned marking layer includes titanium dioxide (TiO₂).
